(19) United States
(12) Patent Application Publication
(10) Pub. No.: US 2016/0090295 A1
(43) Pub. Date: Mar. 31, 2016

(54) MICRO-ELECTRO-MECHANICAL SYSTEM DEVICE WITH LOW SUBSTRATE CAPACITIVE COUPLING EFFECT

(71) Applicants: Ming-Han Tsai, Hsin-Chu (TW); Hsin-Hui Hsu, Hsin-Chu (TW)

(72) Inventors: Ming-Han Tsai, Hsin-Chu (TW); Hsin-Hui Hsu, Hsin-Chu (TW)

(73) Assignee: PixArt Imaging Incorporation, Hsin-Chu (TW)

(21) Appl. No.: 14/790,490

(22) Filed: Jul. 2, 2015

(30) Foreign Application Priority Data
Sep. 26, 2014 (TW) 103133402

(51) Int. Cl. B81B 7/00

(52) U.S. Cl. CPC B81B 7/007; B81B 2207/096

(57) ABSTRACT

The present invention discloses a MEMS device with low substrate capacitive coupling effect, which is manufactured by a CMOS manufacturing process. The MEMS device includes: a substrate; at least one anchor, including an oxide layer connected with the substrate and a connecting structure on the oxide layer; and at least one micro-electro-mechanical structure, connected with the connecting structure. The oxide layer is made by a process step corresponding to a process step for making a field oxide which defines a device region of a transistor in the CMOS manufacturing process. The connecting structure has at least one layer which has an out-of-plane projected area that is smaller than an out-of-plane projected area of the oxide layer. The substrate has plural recesses at an upper surface of the substrate facing the micro-electro-mechanical structure.

### CROSS REFERENCE

The present invention claims priority to TW 103133402, filed on Sep. 26, 2014.

### BACKGROUND OF THE INVENTION

1. Field of Invention

The present invention relates to a Micro-Electro-Mechanical System (MEMS) device with low substrate capacitive coupling effect; particularly, it relates to such a MEMS device having a reduced parasite capacitance and electrostatic effect between a substrate and a micro-electro-mechanical structure by improvements of the anchor and the substrate.

2. Description of Related Art

Please refer to FIG. 1, which shows a cross-sectional view of a conventional MEMS device 10. The conventional MEMS device 10 comprises a substrate 11, an anchor 12 and a micro-electro-mechanical structure 13, which are connected to one another by the described sequence. The micro-electro-mechanical structure 13 is suspended above the substrate 11 by the anchor 12. The conventional MEMS device is manufactured by a CMOS (Complementary Metal-Oxide-Semiconductor) manufacturing process which also manufactures a transistor in a CMOS circuit on the same substrate 11. The transistor includes a gate G, a gate oxide layer GOX, and source and drain S/D. The anchor 12 includes an oxide layer LGO (which is the same layer as the gate oxide layer GOX of the transistor and therefore has the same thickness as the gate oxide layer GOX), a polysilicon layer POLY (which is the same layer as the gate G of the transistor), a first contact/via layer C1, a conducting layer M and a second contact/via layer C2. The first contact/via layer C1, the conducting layer M and the second contact/via layer C2 correspond to the interconnection structures in the CMOS circuit. Because the oxide layer LGO has the same thickness as the gate oxide layer GOX, which is very thin (e.g., about 65 Å), there is an undesirable parasite capacitance between the substrate 11 and the micro-electro-mechanical structure 13. Although the oxide layer LGO has an out-of-plane projected area (a projected area in the out-of-plane direction N) that is smaller than an out-of-plane projected area of the micro-electro-mechanical structure 13, such undesirable parasite capacitance can still cause an undesirable problem. For example, an electrical signal or a voltage level applied to the substrate 11 may interfere with a sensing signal generated from the micro-electro-mechanical structure 13 by this undesirable parasite capacitance.

Besides, usually, there is a voltage difference between the substrate 11 and the micro-electro-mechanical structure 13, which is generated during the operation of the MEMS device 10. Such a voltage difference may generate an undesirable electrostatic force between the substrate 11 and the micro-electro-mechanical structure 13, interfering with the operation of the MEMS device 10.

In view of the above, to overcome the drawback in the prior art, the present invention proposes a MEMS device with low substrate capacitive coupling effect, which is capable of eliminating or reducing the interference from the substrate onto the micro-electro-mechanical structure.

### SUMMARY OF THE INVENTION

From one perspective, the present invention provides a MEMS device, which is manufactured by a CMOS manufacturing process, wherein, during the CMOS manufacturing process, at least one transistor in a CMOS circuit is also manufactured, the transistor having a device region defined by a field oxide layer, the MEMS device comprising: a substrate; at least one anchor, including: an oxide layer connected with the substrate; and a connecting structure on the oxide layer, wherein the oxide layer and the field oxide layer are manufactured by same steps in the CMOS manufacturing process, such that the oxide layer and the field oxide layer have substantially the same thickness; and at least one micro-electro-mechanical structure, which is connected with the connecting structure.

In one embodiment, the connecting structure includes plural layers, and at least one of the plural layers has an out-of-plane projected area that is smaller than an out-of-plane projected area of the oxide layer.

In one embodiment, the connecting structure includes:

at least one interconnection via layer; at least one interconnection metal layer; and at least another one interconnection via layer, wherein all of these interconnection layers have out-of-plane projected areas that are smaller than the out-of-plane projected area of the oxide layer.

In one embodiment, the substrate includes a plurality of recesses at an upper surface of the substrate facing the micro-electro-mechanical structure.

From another perspective, the present invention provides a MEMS device, comprising: a substrate; at least one anchor, including: an oxide layer connected with the substrate; and a connecting structure on the oxide layer; and at least one micro-electro-mechanical structure, which is connected with the connecting structure; wherein the connecting structure includes plural layers, and at least one of the plural layers has an out-of-plane projected area that is smaller than an out-of-plane projected area of the oxide layer.

In one embodiment, the MEMS device is manufactured by a CMOS manufacturing process, and wherein the connecting structure includes: at least one interconnection via layer; at least one interconnection metal layer; and at least another one interconnection via layer, wherein all of these interconnection layers have out-of-plane projected areas that are smaller than the out-of-plane projected area of the oxide layer.

From another perspective, the present invention provides a MEMS device, comprising: a substrate; at least one anchor, including: an oxide layer connected with the substrate; and a connecting structure on the oxide layer; and at least one micro-electro-mechanical structure, which is connected with the connecting structure; wherein the connecting structure includes plural layers, and at least one of the plural layers has an out-of-plane projected area that is smaller than an out-of-plane projected area of the oxide layer.

In one embodiment, the connecting structure includes plural layers, and at least one of the plural layers has an out-of-plane projected area that is smaller than an out-of-plane projected area of the oxide layer.

In one embodiment, the MEMS device is manufactured by a CMOS manufacturing process, wherein the connecting structure includes: at least one interconnection via layer; at least one interconnection metal layer; and at least another one interconnection via layer, wherein all of these interconnection layers have out-of-plane projected areas that are smaller than the out-of-plane projected area of the oxide layer.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-sectional view of a conventional MEMS device.

FIGS. 2A-2C and 3A-3C show several embodiments of the MEMS device with low substrate capacitive coupling effect according to the present invention.

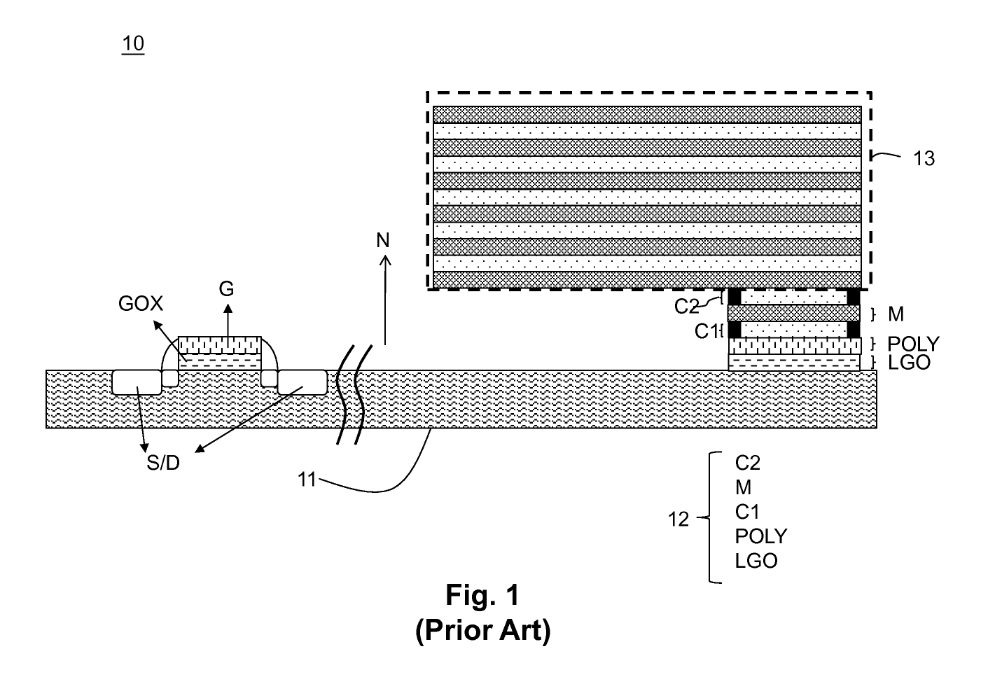

### DESCRIPTION OF THE PREFERRED EMBODIMENTS

The above and other technical details, features and effects of the present invention will be will be better understood with regard to the detailed description of the embodiments below, with reference to the drawings. The drawings as referred to throughout the description of the present invention are for illustration only, to show the interrelations between the layers, but not drawn according to actual scale.

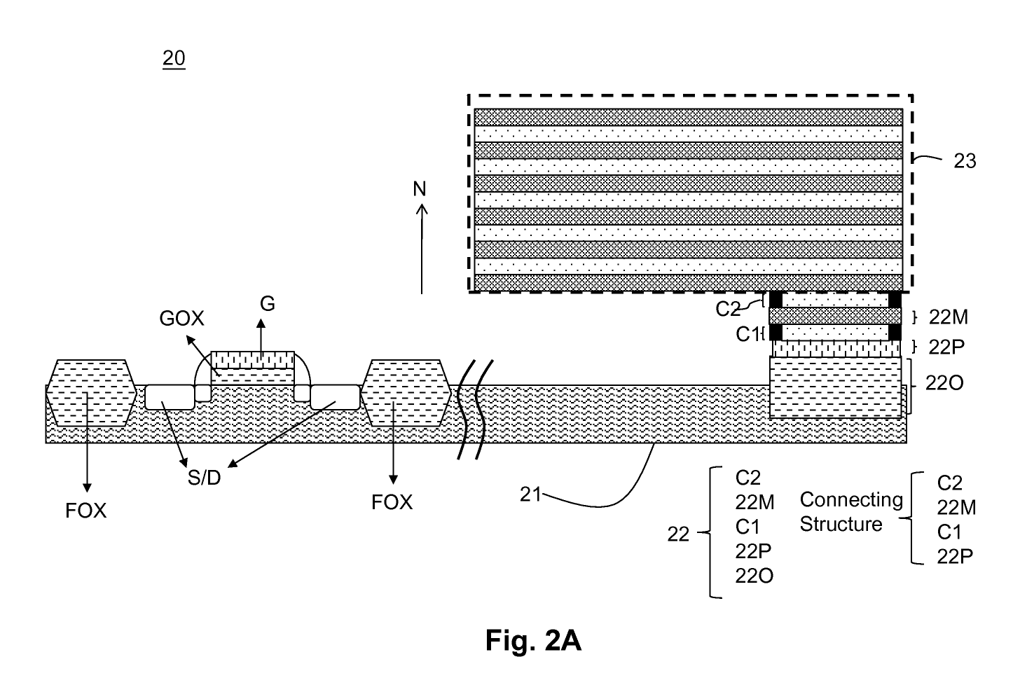

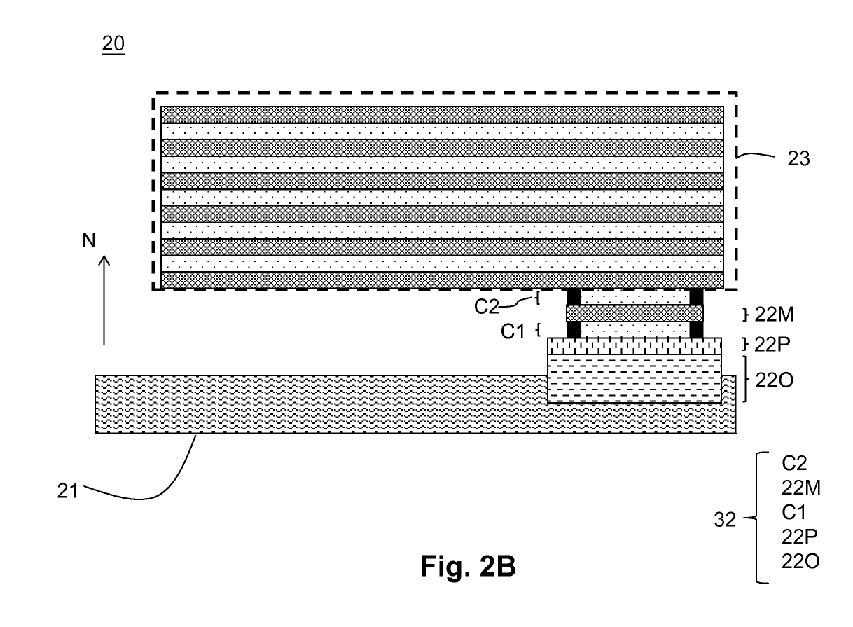

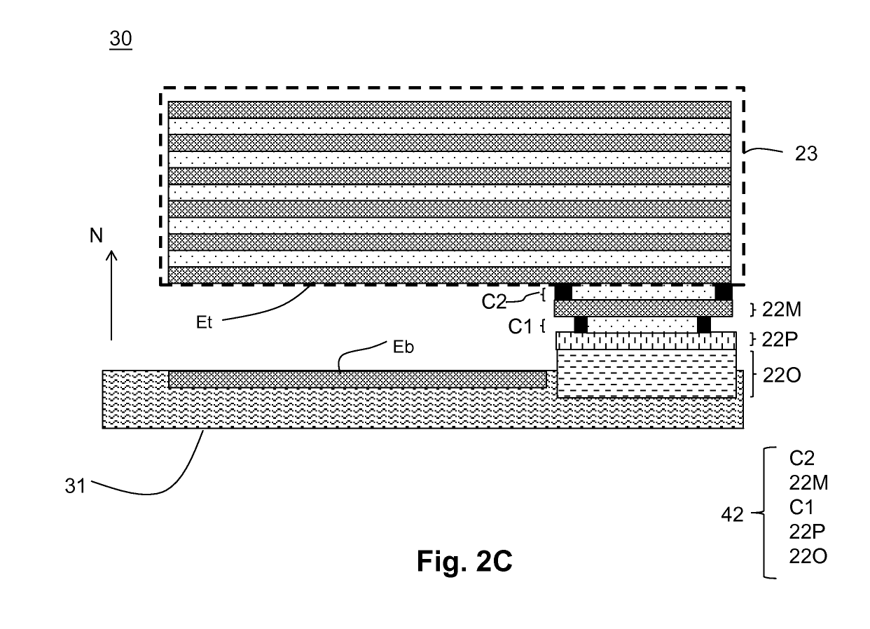

Please refer to FIG. 2A, which shows a MEMS device 20 with low substrate capacitive coupling effect according to an embodiment of the present invention. The MEMS device 20 is manufactured by a CMOS manufacturing process; during the CMOS manufacturing process, a CMOS circuit and at least one transistor in the CMOS circuit (referring to the left side of FIG. 2A) are also manufactured on the same substrate 21. The transistor includes a gate G, a gate oxide layer GOX, and source and drain S/D. The device region of the transistor is defined by a field oxide layer (FOX), wherein the field oxide FOX for example can be formed by local oxidation of silicon (LOCOS) as shown in FIG. 2A, or can be a shallow trench isolation (STI, not shown). The MEMS device 20 includes a substrate 21, at least one anchor 22 (for simplicity, FIG. 2A only shows one anchor 22; however, the number of the anchor is not limited to one), and at least one micro-electro-mechanical structure 23 (for simplicity, FIG. 2A only shows one micro-electro-mechanical structure 23; however, the number of the micro-electro-mechanical structure 23 is not limited to one). The anchor 22 includes an oxide layer 220 and a connecting structure on the oxide layer 220. The oxide layer 220 and the field oxide layer FOX are manufactured by the same steps in the CMOS manufacturing process, so the oxide layer 220 and the field oxide layer FOX have substantially the same thickness. The oxide layer 220 is connected to the substrate 21. The micro-electro-mechanical structure 23 is connected to the connecting structure of the anchor 22, so that the micro-electro-mechanical structure 23 is suspended above the substrate 21. In this embodiment, the thickness of the oxide layer 220 is larger than the thickness of the gate oxide layer GOX.

The number of the layers within the connecting structure can be designed according to the required height of the anchor 22. These layers within the connecting structure can be made by material layers corresponding to the gate and the interconnection structures in the CMOS circuit, so that the connecting structure can be manufactured as the CMOS manufacturing process manufactures the CMOS circuit. In one embodiment, the anchor 22 includes, from bottom to top, an oxide layer 220, a first connecting layer 22P (which can be made by, for example but not limited to, a material layer corresponding to the gate in the CMOS manufacturing process) and a first contact/via layer C1 (which can be made by, for example but not limited to, a material layer corresponding to the interconnection contact layer in the CMOS manufacturing process), which are stacked one on another. In another embodiment, the anchor 22 includes, from bottom to top, an oxide layer 220, a first connecting layer 22P (which can be made by, for example but not limited to, a material layer corresponding to the gate in the CMOS manufacturing process), a first contacting/via layer C1 (which can be made by, for example but not limited to, a material layer corresponding to the interconnection contact layer in the CMOS manufacturing process), a second connecting layer 22M (which can be made by, for example but not limited to, a material layer corresponding to the interconnection metal layer in the CMOS manufacturing process) and a second contacting/via layer C2 (which can be made by, for example but not limited to, a material layer corresponding to the interconnection via layer in the CMOS manufacturing process). The number of the layers within the connecting structure is not limited to what are shown in the figure; there can be more or less layers, and the topmost layer is not necessarily a contact/via layer.

That “the oxide layer 220 and the field oxide layer FOX are manufactured by the same steps in the CMOS manufacturing process, so the oxide layer 220 and the field oxide layer FOX have substantially the same thickness” indicates that when the CMOS manufacturing process manufactures the field oxide layer FOX, the oxide layer 220 is manufactured at the same time. Because the oxide layer 220 and the field oxide layer FOX are manufactured by the same steps, the oxide layer 220 and the field oxide layer FOX have substantially the same thickness, but “substantially the same thickness” does not mean that their thicknesses must be exactly the same. Due to different local pattern densities, process non-uniformity, or other reasons, their thicknesses maybe slightly different. In comparison with the oxide layer LGO of the prior art, in this embodiment, the distance between the connecting structure and the substrate 21 (i.e., the thickness of the oxide layer 220) is higher than the thickness of the oxide layer LGO, so the parasite capacitance between the connecting structure and the substrate 21 is lower than that in the prior art.

Please refer to FIG. 2B, which shows a MEMS device 20 with low substrate capacitive coupling effect according to another embodiment of the present invention. For simplicity, the transistor and the field oxide layer FOX are omitted. This embodiment is similar to the embodiment shown in FIG. 2A, but is different in that: the connecting structure includes at least one layer which has an out-of-plane projected area (a projected area in the out-of-plane direction N) that is smaller than an out-of-plane projected area of the oxide layer 220. The direction N in FIG. 2B represents the out-of-plane direction. As shown in FIG. 2B, the cross-sectional widths of the first contacting/via layer C1, the second connecting layer 22M and the second contacting/via layer C2 are all smaller than the cross-sectional width of the oxide layer 220, indicating that the first contacting/via layer C1, the second connecting layer 22M and the second contacting/via layer C2 all have an out-of-plane projected area that is smaller than an out-of-plane projected area of the oxide layer 220. When the connecting structure has at least one layer which has an out-of-plane projected area that is smaller than an out-of-plane projected area of the oxide layer 220, the parasite capacitance can be further reduced.

Please refer to FIG. 2C, which shows a MEMS device 30 with low substrate capacitive coupling effect according to yet another embodiment of the present invention. This embodiment is similar to the embodiment shown in FIG. 2B, but is different in that: the connecting structure has only one layer which has an out-of-plane projected area that is smaller than an out-of-plane projected area of the oxide layer 220. This embodiment shows that the number and position(s) of the layer(s) which has/have an out-of-plane projected area smaller than an out-of-plane projected area of the oxide layer 220 are not limited to the arrangement shown in FIG. 2B.

Please still refer to FIG. 2C. In this embodiment, the substrate 31 has at least one lower electrode Eb, and the micro-electro-mechanical structure 23 has an upper electrode Et corresponding to the lower electrode Eb. The relative electrical relationship between the upper electrode Et and the lower electrode Eb can be used to sense the movement of the micro-electro-mechanical structure 23.

Note that the above-mentioned feature that “the connecting structure has at least one layer which has an out-of-plane projected area that is smaller than an out-of-plane projected area of the oxide layer 220” can be implemented alone, and is not necessarily implemented together with the above-mentioned feature that “the oxide layer 220 and the field oxide layer FOX are manufactured by the same steps in the CMOS manufacturing process, so the oxide layer 220 and the field oxide layer FOX have substantially the same thickness”. In other words, in another embodiment, the oxide layer 220 and the gate oxide layer can be manufactured by the same steps in the CMOS manufacturing process so that the oxide layer 220 and the gate oxide layer have substantially the same thickness, but the connecting structure has at least one layer which has an out-of-plane projected area that is smaller than an out-of-plane projected area of the oxide layer 220, and this can still reduce the parasite capacitance.

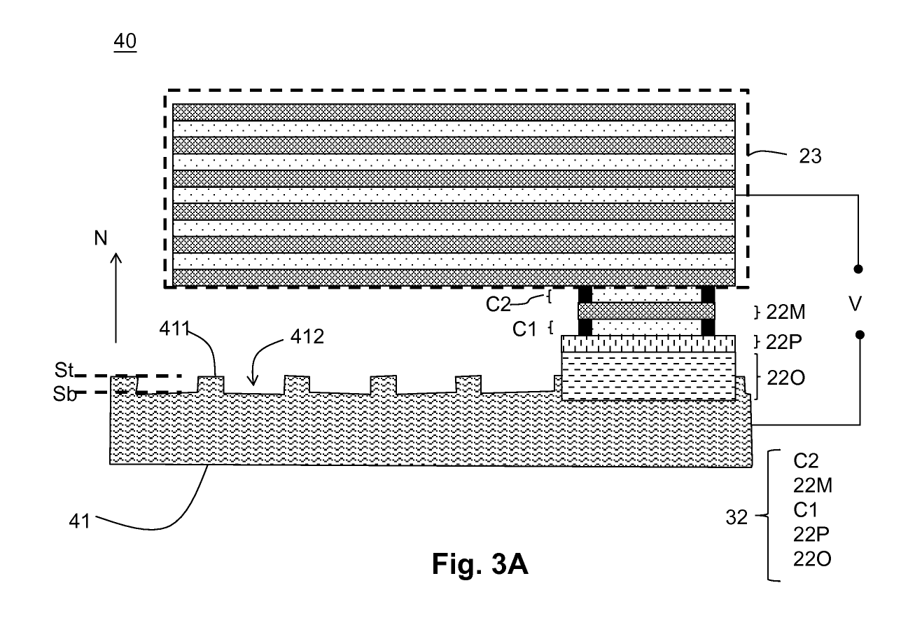

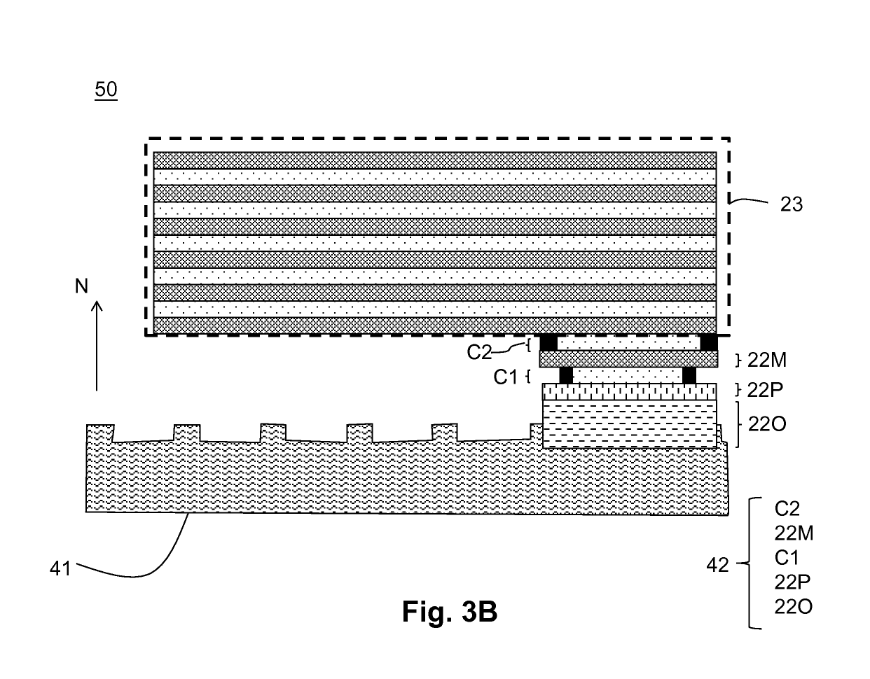

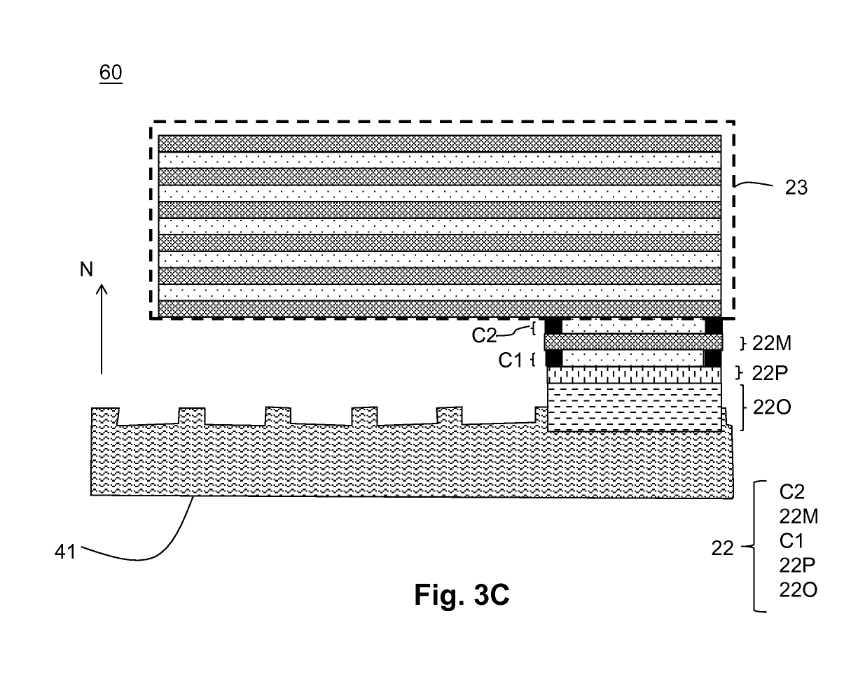

Please refer to FIG. 3A, which shows a MEMS device 40 with low substrate capacitive coupling effect according to still another embodiment of the present invention. The structure of the MEMS device 40 in this embodiment is similar to the structure of the MEMS device 20 shown in FIG. 2B, but is different in that: the substrate 41 of FIG. 3A includes plural recesses 412 at an upper surface of the substrate 41 (with reference to the surface level St); or, from another perspective, the same structure can also be regarded as: the substrate 41 includes plural protrusions 411 at an upper surface of the substrate 41 (with reference to the surface level Sb). The following description is based on taking the surface level St as the reference level; however, the two perspectives are equivalent to each other. The substrate 41 includes plural recesses 412 (protrusions 411) at an upper surface of the substrate 41 which faces the micro-electro-mechanical structure 23. In one embodiment, the recesses 412 can be made during the process steps manufacturing the STI structure; or in another embodiment, the recesses 412 can be made by an additional etching process. The recesses 412 provides a function as thus. Usually, there is a voltage difference between the substrate 41 and the micro-electro-mechanical structure 23 during the operation of the MEMS device 40. Although such voltage difference is required for the operation of the MEMS device 40, it will generate an undesirable electrostatic force between the substrate 41 and the micro-electro-mechanical structure 23. Such undesirable electrostatic force may affect the sensing result of the movement of the micro-electro-mechanical structure 23 if it is too large. The above-mentioned recesses 412 increase the average distance between the substrate 41 and the micro-electro-mechanical structure 23, to thereby reduce the undesirable effect from the electrostatic force. As a result, the interference by the electrostatic force during the operation of the MEMS device 40 can be reduced.

Please refer to FIG. 3B and FIG. 3C, which show a MEMS device 50 with low substrate capacitive coupling effect and a MEMS device 60 with low substrate capacitive coupling effect according to two other embodiments of the present invention. The structures of the MEMS devices 50 and 60 are similar the structure of the MEMS device 40 shown in FIG. 3A, but are different in that: the anchor 42 of the MEMS device 50 and the anchor 22 of the MEMS device 60 are different from the anchor 32 of the MEMS device 30. The details of such differences have been explained with reference to FIGS. 2A-2C.

In addition, the design of the above-mentioned anchors 22, 32 and 42 is also capable of reducing package stress. When the MEMS device of the present invention is packaged, the molding plastic material surrounds the MEMS device. After the packaged process is finished and the product drops to a normal temperature, the temperature variance due to different thermal coefficients of different materials may cause a deformation of the internal structure. However, because some of the layers of the anchors 22, 32 and 42 have relatively smaller out-of-plane projected area, the amount of deformation can be reduced.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. In view of the foregoing, the spirit of the present invention should cover all such and other modifications and variations, which should be interpreted to fall within the scope of the following claims and their equivalents.

What is claimed is:

1. A Micro-Electro-Mechanical System (MEMS) device, which is manufactured by a Complementary Metal-Oxide-Semiconductor (CMOS) manufacturing process, wherein, during the CMOS manufacturing process, at least one transistor in a CMOS circuit is also manufactured, the transistor having a device region defined by a field oxide layer, the MEMS device comprising:
a substrate;
at least one anchor, including:
an oxide layer connected with the substrate; and
a connecting structure on the oxide layer,
wherein the oxide layer and the field oxide layer are manufactured by same steps in the CMOS manufacturing process, such that the oxide layer and the field oxide layer have substantially the same thickness; and
at least one micro-electro-mechanical structure, which is connected with the connecting structure.

2. The MEMS device of claim 1, wherein the connecting structure includes plural layers, and at least one of the plural layers has an out-of-plane projected area that is smaller than an out-of-plane projected area of the oxide layer.

3. The MEMS device of claim 2, wherein the connecting structure includes: at least one interconnection via layer; at least one interconnection metal layer; and at least another interconnection via layer, wherein all of these interconnection layers have out-of-plane projected areas that are smaller than the out-of-plane projected area of the oxide layer.

4. The MEMS device of claim 1, wherein the substrate includes a plurality of recesses at an upper surface of the substrate facing the micro-electro-mechanical structure.

5. A MEMS device, comprising:
a substrate;
at least one anchor, including:
an oxide layer connected with the substrate; and
a connecting structure on the oxide layer; and
at least one micro-electro-mechanical structure, which is connected with the connecting structure;
wherein the connecting structure includes plural layers, and at least one of the plural layers has an out-of-plane projected area that is smaller than an out-of-plane projected area of the oxide layer.

6. The MEMS device of claim 5, wherein the MEMS device is manufactured by a CMOS manufacturing process, and wherein the connecting structure includes: at least one interconnection via layer; at least one interconnection metal layer; and at least another one interconnection via layer, which are all corresponding in the CMOS manufacturing process, wherein all of these interconnection layers have out-of-plane projected areas that are smaller than the out-of-plane projected area of the oxide layer.

7. A MEMS device, comprising:
a substrate, which includes a plurality of recesses;
at least one anchor, including:
an oxide layer connected with the substrate; and
a connecting structure on the oxide layer; and
at least one micro-electro-mechanical structure, which is connected with the connecting structure;
wherein the recesses are at an upper surface of the substrate facing the micro-electro-mechanical structure.

8. The MEMS device of claim 7, wherein the connecting structure includes plural layers, and at least one of the plural layers has an out-of-plane projected area that is smaller than an out-of-plane projected area of the oxide layer.

9. The MEMS device of claim 8, wherein the MEMS device is manufactured by a CMOS manufacturing process, and wherein the connecting structure includes: at least one interconnection via layer; at least one interconnection metal layer; and at least another one interconnection via layer, wherein all of these interconnection layers have out-of-plane projected areas that are smaller than the out-of-plane projected area of the oxide layer.
